(19) United States
(12) Patent Application Publication
(10) Pub. No.: US 2007/0217173 A1
(43) Pub. Date: Sep. 20, 2007

(54) Circuit board

(75) Inventors: Daisuke Mizutani, Kawasaki (JP); Tatsuhiko Tajima, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/447,866

(22) Filed: Jun. 7, 2006

(30) Foreign Application Priority Data
Mar. 16, 2006 (JP) 2006-072150

(51) Int. Cl. H05K 7/00

(52) U.S. Cl. 361/760

(57) ABSTRACT

The circuit board comprises a through-hole via which is formed in a through-hole passed through a substrate and includes a via portion electrically connected to a part of a plurality of interconnection layers at the inside wall of the through-hole and a pad portion formed on a surface of the substrate in a region surrounding the through-hole and is connected to the via portion. In the circuit board, an opening is formed for passing through the through-hole via out of connection with a constant-voltage interconnection layer in the region where the through-holes is formed. The constant-voltage interconnection layer is the interconnection layer nearest to the pad portion, and an outer diameter of the pad portion is larger than a diameter of the opening formed in the constant-voltage interconnection layer, whereby a capacitor including the pad portion and the constant-voltage interconnection layer as a pair of electrodes is formed.

### CROSS-REFERENCE TO RELATED APPLICATIONS

This application is based upon and claims the benefit of priority from the prior Japanese Patent Application No. 2006-072150, filed on Mar. 16, 2006, the entire contents of which are incorporated herein by reference.

### BACKGROUND OF THE INVENTION

The present invention relates to a circuit board of a multilayer structure including a through-hole via.

As network devices speed up, the large-scale highly multilayer circuit boards used in the communication stations and high end servers, etc. must make transmissions of high frequencies exceeding 1 GHz. However, for the high signal frequencies exceeding 1 GHz, it is important to make the impedance matching with the characteristic impedance of the interconnections and also reduce the frequency-dependent loss. To this end, for the circuit boards, studies are made to decrease the loss of the general three-dimensional transmission line including the planar interconnection patterns and also the inter-layer connection vias.

In the circuit board, insulating materials and interconnection materials are being developed for decreasing the loss of the transmission line, and on the other hand, it is a problem to decrease the loss due to open stubs connected to through-hole vias. Here, the open stub is generally a transmission line connected to nothing. In the circuit board, surplus portions of through-hole vias for the inter-layer connection of a multilayer circuit board, which do not contribute to the connections among the interconnection layers, act the open stubs. Such open stubs take place to some degree in the industrial fabrication of the circuit board. The number of the open stub is increased as the number of layers forming the circuit board is larger, and the transmission loss is increased.

As methods for solving this problem are proposed circuit board fabricating methods, such as a method called back-drilling which, after a circuit board has been fabricated, open stubs are scraped off, and a build-up method which uses no through-hole vias.

Related arts are disclosed in, e.g., Reference 1 (Japanese published unexamined patent application No. 2001-203300).

However, the conventional method for fabricating the circuit board described above much increase the fabrication cost. A circuit board which can decrease the transmission loss due to the open stubs without much increasing the fabrication cost is expected.

### SUMMARY OF THE INVENTION

An object of the present invention is to provide a circuit board which can decrease the transmission loss due to the open stub without much increasing the fabrication cost.

According to one aspect of the present invention, there is provided a circuit board comprising: a substrate formed of a plurality of interconnection layers and a plurality of insulating layers alternately laid one on another; and a through-hole via including a via portion which is formed in a through-hole formed in the substrate and is electrically connected to a part of said plurality of interconnection layers, and a pad portion which is formed on a surface of the substrate in a region surrounding the through-hole and is connected to the via portion, at least one of said plurality of interconnection layers being a constant-voltage interconnection layer fixed to a certain voltage, and an opening being formed for passing through the through-hole via out of connection with the constant-voltage interconnection layer in a region where the through-hole is formed, the constant-voltage interconnection layer being the interconnection layer which is nearest the pad portion, an outer diameter of the pad portion being larger than a diameter of the opening formed in the constant-voltage interconnection layer, and the pad portion, the constant-voltage interconnection layer, and the insulating layer formed between the pad portion and the constant-voltage interconnection layer forming a capacitor.

According to the present invention, in the circuit board which comprises a substrate formed of a plurality of interconnection layers and insulating layers alternately laid one on another, and a through-hole via including a via portion formed in a through-hole passed through the substrate and electrically connected to a part of said plurality of interconnection layers and a pad portion formed in a region of a surface of the substrate surrounding the through-hole and connected to the via portion, and in which at least one layer of said plurality of interconnection layers is a constant-voltage interconnection layer whose voltage is fixed to a certain voltage and an opening for passing the through-hole out of connection with a through-hole via is formed in a region of the constant-voltage interconnection layer where the through-hole is formed, the constant-voltage interconnection layer is an interconnection layer nearest to the pad portion, and an outer diameter of the pad portion is larger than a diameter of the opening formed in the constant-voltage interconnection layer, whereby a capacitor including a pair of the pad portion and the constant-voltage interconnection layer as a pair of electrodes can be formed. Thus, the resonance frequency of the open stub can be shifted. The capacitance of the capacitor can be controlled by an area of the overlap between the constant-voltage interconnection layer and the pad portion, i.e., a clearance diameter of the constant-voltage interconnection layer and an outer diameter of the pad portion, whereby a capacitor of an arbitrary capacitance can be realized only by changing patterns of the interconnection layer and the via opening pad by the conventional circuit board fabricating method. Thus, the reflection loss in an arbitrary frequency range can be decreased, and high-speed transmission circuit board having the transmission loss in the open stub decreased can be provided easily and at low costs.

### BRIEF DESCRIPTION OF THE DRAWINGS

FIG. 1 is a diagrammatic sectional view of the circuit board explaining the open stub.

FIGS. 2A and 2B are diagrammatic views of the circuit board according to one embodiment of the present invention, which show the structure.

FIG. 3 is a view of an equivalent circuit of the surplus part of the through-hole via.

FIG. 4 is a graph of the frequency dependency of the transmission loss given by simulation.

FIGS. 5 to 7 are diagrammatic views of the circuit board according to modifications of the embodiment of the present invention, which show a structure thereof.

FIGS. 8, 9A-9B and 10A-10B are sectional views of the circuit board according to the- embodiment of the present invention in the steps of the method for fabricating the same, which show the method.

### DETAILED DESCRIPTION OF THE INVENTION

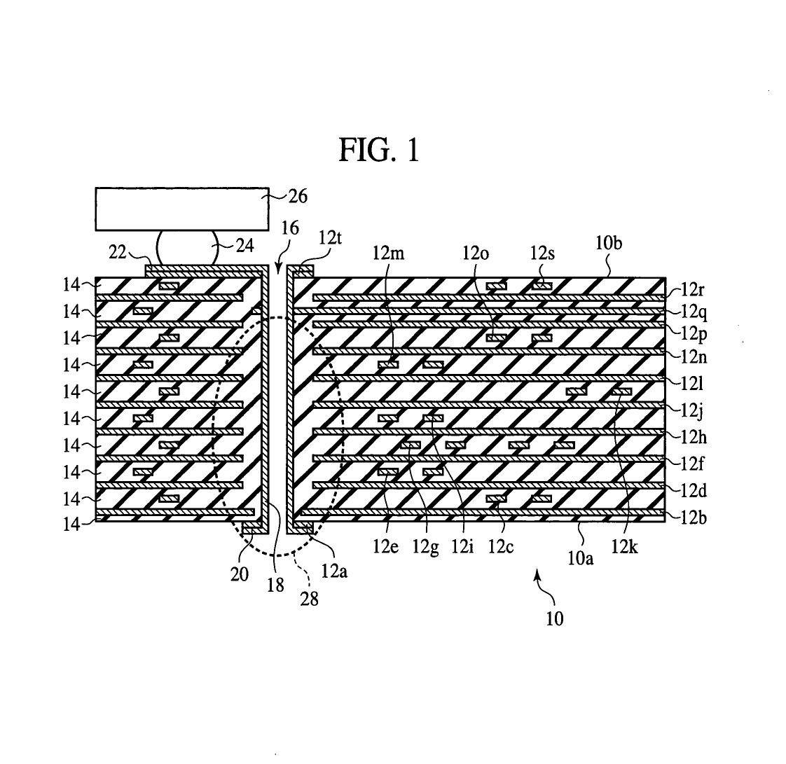

The circuit board and method for fabricating the same according to one embodiment of the present invention will be explained with reference to FIGS. 1 to 10B.

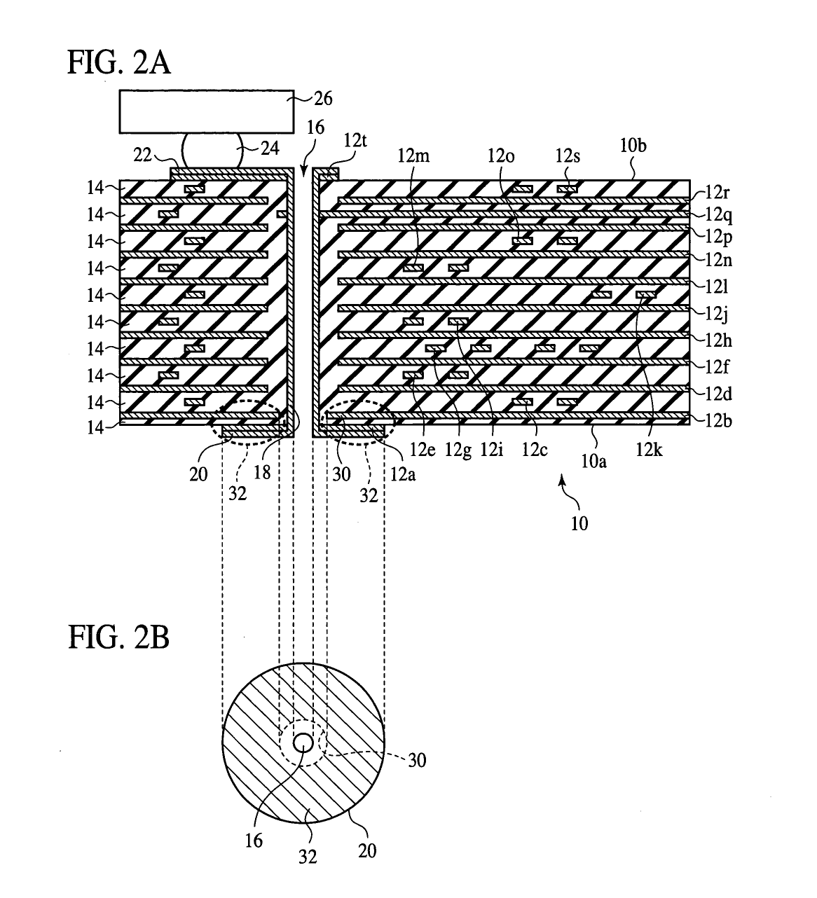

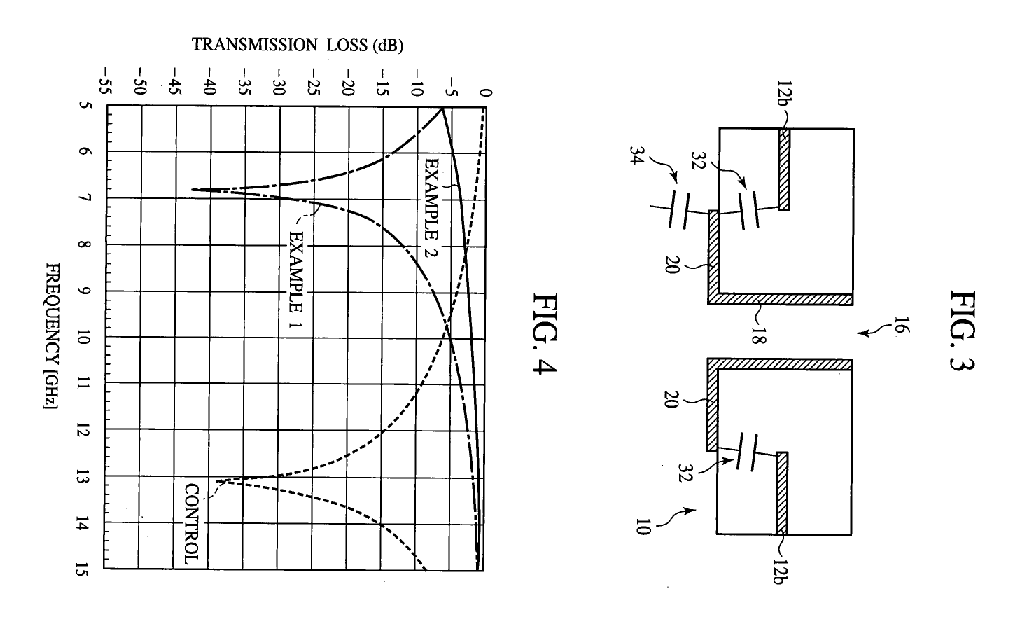

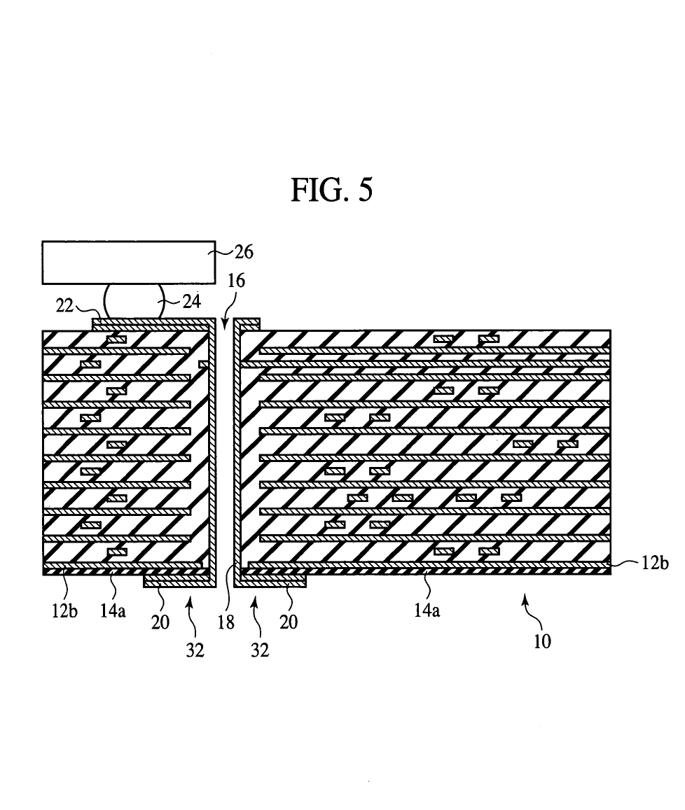

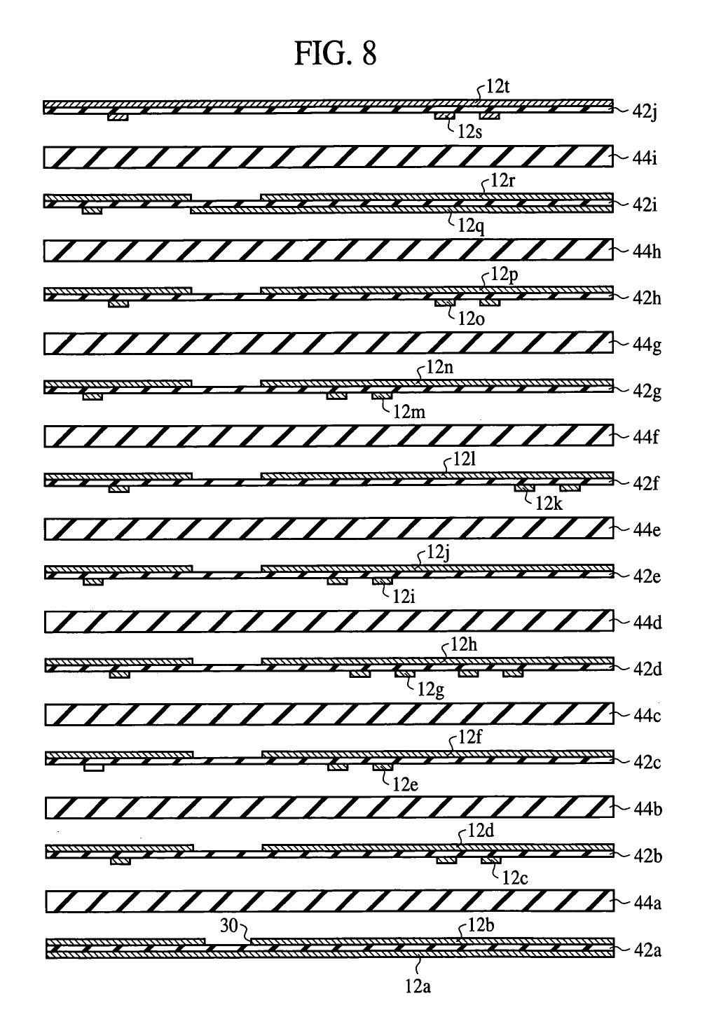

FIG. 1 is a diagrammatic sectional view of the circuit board explaining the open stub. FIGS. 2A and 2B are diagrammatic views showing a structure of the circuit board according to the present embodiment. FIG. 3 shows an equivalent circuit of a surplus portion of a through-hole via. FIG. 4 is a graph of the frequency dependency of the transmission loss given by simulation. FIGS. 5 to 7 are diagrammatic views of the circuit board according to modifications of the present embodiment, which show structure thereof. FIGS. 8 to 10B are sectional views of the circuit board according to the present embodiment in the steps of the method for fabricating the same, which show the method.

First, the open stub of the circuit board will be explained with reference to FIG. 1.

A substrate 10 which is the base of the circuit board is formed by stacking a plurality of interconnection layers 12 having a prescribed interconnection pattern formed in one on another with insulating films 14 formed therebetween. In the circuit board shown in FIG. 1, interconnection layers 12a-12t are stacked with insulating layers 14 formed therebetween.

A through-hole 16 is formed through the substrate 10. In the through-hole 16, a through-hole via 18 is formed. The through-hole via 18 has a via portion formed on an inside wall of the through-hole 16, and pad portions formed on a surfaces 10a, 10b of the substrate 10 in regions surrounding the through-hole 16. Here, the pad portion of the through-hole via 18 on the surface 10a of the substrate 10 and the interconnection layer 12a formed on the surface 10a of the substrate 10 are together called a via opening pad 20, and the pad portion of the through-hole via 18 on the surface 10b of the substrate 10 and the interconnection layer 12t formed on the surface 10b of the substrate 10 are together called an electrode pad 22.

The through-hole via 18 is electrically connected to the interconnection layer 12t at the surface 10b and is electrically connected to the interconnection layer 12q at the inside wall of the through-hole 16. That is, in the circuit board shown in FIG. 1, the through-hole via 18 functions as an inter-layer interconnection for electrically connecting the interconnection layer 12t and the interconnection layer 12q to each other. A semiconductor chip 26 is connected to the electrode pad 22 via a solder bump 24.

Here, in the circuit board shown in FIG. 1, the through-hole via 18 positioned nearer the surface 10a than the interconnection layer 12q (indicated by the dotted line 28 in FIG. 1) does not form an electric interconnection path but forms a transmission line connected forward to nothing, i.e., an open stub.

The open stub is often positively utilized for the purposes of impedance matching, etc. The above-described open stub, however, is formed of the surplus part of the through-hole via 18, and it is actually impossible to control the length, etc. of the transmission line. Accordingly, such open stub, that takes place as a surplus part of the through-hole via 18, is a cause for the transmission loss due to impedance mismatching.

Next, the circuit board according to the present embodiment will be explained with reference to FIGS. 2A and 2B. FIG. 2A is a diagrammatic sectional view of the circuit board according to the present embodiment, which shows a structure thereof. FIG. 2B is a plan view of the pad portion of the via opening of the circuit board according to the present embodiment, which shows a structure thereof.

The substrate 10, which is the base of the circuit board, is formed by stacking a plurality of interconnection layers 12 having a prescribed interconnection pattern formed in one on another with the insulating films 14 formed therebetween. In the circuit board shown in FIG. 2A, interconnection layers 12a-12t are stacked with the insulating layers 14 formed therebetween.

A through-hole 16 is formed through the substrate 10. In the through-hole 16, the through-hole via 18 is formed. The through-hole via 18 has a via portion formed on the inside wall of the through-hole 16, and the pad portions formed on a surfaces 10a, 10b of the substrate 10 in regions surrounding the through-hole 16. Here, the pad portion of the through-hole via 18 on the surface 10a of the substrate 10 and the interconnection layer 12a formed on the surface 10a of the substrate 10 are together called a via opening pad 20, and the pad portion of the through-hole via 18 on the surface 10b of the substrate 10 and the interconnection layer 12t formed on the surface 10b of the substrate 10 are together called an electrode pad 22.

The through-hole via 18 is electrically connected to the interconnection layer 12t at the surface 10b and is electrically connected to the interconnection layer 12q at the inside wall of the through-hole 16. That is, in the circuit board shown in FIG. 2, the through-hole via 18 functions as an inter-layer interconnection for electrically connecting the interconnection layer 12t and the interconnection layer 12q to each other. A semiconductor chip 26 is connected to the electrode pad 22 via a solder bump 24.

Here, the circuit board according to the present embodiment is characterized mainly in that the interconnection layer 12b of the interconnection layers 12b-12t, which is nearest to the via opening pad 20 is the constant-voltage interconnection layer whose voltage is fixed to a certain voltage, and the via opening pad 20 is opposed to the interconnection layer 12b via the insulating layer 14. Specifically, as shown in FIG. 2B, an outer diameter of the via opening pad 20 has a value larger than a value of a diameter of the opening 30 (clearance diameter) provided in the interconnection layer 12b out of connection to the through-hole via 18.

That is, in the circuit board according to the present embodiment, a capacitor 32 including the insulating layer 14 as the capacitor dielectric film, and the interconnection layer 12b and the via opening pad 20 as a pair of electrodes sandwiching the capacitor dielectric film is connected between the end of the surplus part of the through-hole via 18 (via opening pad 20) and the constant-voltage interconnection layer (interconnection layer 12b). As shown in FIG. 2B by a hatched region, the capacitor 32 is formed in a doughnut shape surrounding the through-hole 16.

The capacitor 32 is thus disposed between the open stub of the through-hole via and the constant-voltage interconnection layer, whereby the resonance frequency of the open stub can be shifted. Thus, the reflection loss in an arbitrary frequency range can be decreased.

The capacitance of the capacitor 32 varies depending on an area of the overlap between the interconnection layer 12b and the via opening pad 20, i.e., a clearance diameter of the interconnection layer 12b and an outer diameter of the via opening pad 20. Accordingly, the capacitor 32 can have an arbitrary capacitance only by changing patterns of the interconnection layer 12b and the via opening pad 20 in the conventional method for fabricating the circuit board.

The constant-voltage interconnection layer disposed near the via opening pad 20 may be an interconnection layer fixed to a constant voltage and can be a ground layer fixed to the ground potential or a power supply layer fixed to a power supply voltage. The interconnection layer fixed to a constant voltage is used, whereby the transmission loss of the open stub can be stably decreased without causing characteristics change of the capacitor due to input signal changes.

In the conventional circuit board, for ensuring the fabrication margin, etc., the clearance diameter of the interconnection layers for the through-hole are made sufficiently large and is larger in comparison with the diameter of the via opening pad. In the conventional circuit board, when an interconnection layer forming a constant-voltage interconnection layer is formed immediately below the via opening pad, a capacitor is formed between the via opening pad and the constant-voltage interconnection layer. However, the capacitance value of the capacitor is inversely proportional to the inter-electrode distance, and a capacitance value sufficient to decrease the loss in the open stub cannot be obtained.

In the prior art, as described above, the structures of the circuit board having no open stubs have been studied. As to the method of providing a discrete capacitor in a circuit board to thereby decrease the loss in an arbitrary frequency range, many means and structures for the parts-incorporated circuit boards are being studied. However, it is difficult to dispose a discrete capacitor in a circuit board with high yields, and it is also necessary that materials of the capacitor must be compatible with the process of the circuit board fabrication. It is difficult to fabricate the capacitor-incorporated circuit board at low costs.

It is also possible to dispose a capacitor on the substrate surface to thereby decrease the loss. In this case, the locations of the capacitor must be near the open stub openings. When the capacitor is disposed on the substrate surface, the loss decreasing effect given by the same capacitance is lower than when the capacitor is disposed immediately below the via opening pad.

FIG. 3 shows the equivalent circuit of the surplus part of the through-hole via 18. The capacitor between the via opening pad 20 and the interconnection layer 12b is the above-described capacitor 32. In contrast to this, a capacitor connected to the surface of the via opening pad 20 forms a surface capacitor 34 as shown in FIG. 3 and cannot provide the effect equivalent to that provided by the capacitor 32.

FIG. 4 is a graph of the frequency dependency of the transmission loss given by simulation. In this simulation, a circuit board having a 300 μm-through-hole diameter and a 1500 μm-length open stub was assumed.

In the graph, the dotted line (a Control) indicates the characteristics of the conventional structure having a via opening pad of a 600 μm-outer diameter and a ground layer as the constant-voltage interconnection layer of a 1000 μm-clearance diameter. The capacitance of the capacitor of this case is 0.2 pF. The one dot chain line (Example 1) indicates the characteristics of the structure of the present invention having a via opening pad of a 800 μm-outer diameter and a ground layer as the constant-voltage interconnection layer of a 800 μm-clearance diameter. The capacitance of the capacitor of this case is 1.0 pF (5 times that of the conventional structure). The solid line (Example 2) indicates the characteristics of the structure of the present invention having a via opening pad of a 1000 μm-outer diameter and a ground layer as the constant-voltage interconnection layer of a 800 μm-clearance diameter. The capacitance of the capacitor of this case is 10 pF (50 times that of the conventional structure). On the vertical axis of the graph, values of the transmission loss for one through-hole via are taken.

In Control, the resonance frequency is about 13.1 GHz, and the value of the transmission loss at 10 GHz is about 6.5 dB. On the other hand, in Example 1, the resonance frequency is decreased to about 6.8 GHz, and the value of the transmission loss at 10 GHz can be decreased to about 5 dB. In Example 2, the resonance frequency is further decreased, and the value of the transmission loss at 10 GHz can be decreased to about 2 dB.

It is preferable that the capacitance value of the capacitor 32 is suitably set so that the transmission loss for a used signal frequency can be sufficiently small. For example, in the circuit board of FIG. 4 used in the simulation, when the used signal frequency is assumed to be 10 GHz, the capacitor 32 between the open stub of the through-hole via 18 and the ground layer has a capacitor capacitance value which is not less than 5 times, preferably not less than 50 times the capacitance of the conventional structure, in which the end of the via opening pad and the end of the ground layer are largely apart from each other, whereby the transmission loss due to the open stub of the through-hole via 18 can be decreased. Otherwise, a capacitor 32 which makes a frequency at a resonance point not more than 70% (e.g., 6.8 GHz) or not less than 130% (e.g., 13.1 GHz) of a center frequency (e.g., 10.0 GHz) of a used frequency range is disposed between the end of the surplus part of the through-hole via 18 and the ground layer, whereby the transmission loss due to the surplus part of the through-hole via 18 can be decreased.

Various methods for changing the capacitance of the capacitor 32 are considered. However, the above-described method of changing the outer diameter of the via opening pad 20 and the clearance diameter of the interconnection layer 12b for the through-hole 16 is very effective because the fabrication steps do not have to be changed, and the fabrication cost is not increased.

When only increasing the area of the overlap between the interconnection layer 12b forming the ground layer and the via opening pad 20 cannot ensure a sufficient capacitance due to layout restrictions, etc., the capacitance can be increased by, e.g., the following methods.

The capacitance can be controlled by the opposed area between opposed electrodes and also by changing the dielectric constant and/or the film thickness of the dielectric film. To further change the capacitance of the capacitor 32, as exemplified in FIG. 5, the insulating layer formed between the interconnection layer 12b forming the ground layer and the via opening pad 20 may be formed of an insulating layer 14a of a high dielectric constant, which may be formed of a ferroelectric material or others.

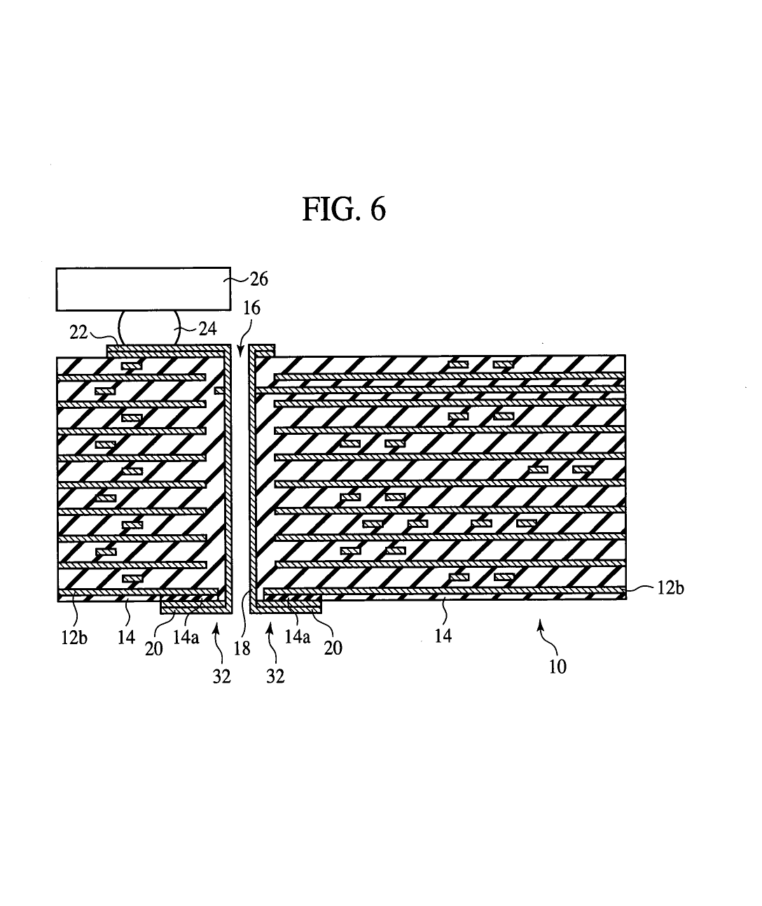

In this case, as shown in FIG. 5, the entire of the insulating layer 14a may be formed of a ferroelectric material, or as shown in FIG. 6, an insulating layer 14a of a ferroelectric material or others may be formed selectively in a region between the interconnection layer 12b forming the ground layer and the via opening pad 20. The insulating layer 14a may have the layer structure of layers of a plurality of different materials, such as a ferroelectric layer, and an adhesion layer or others.

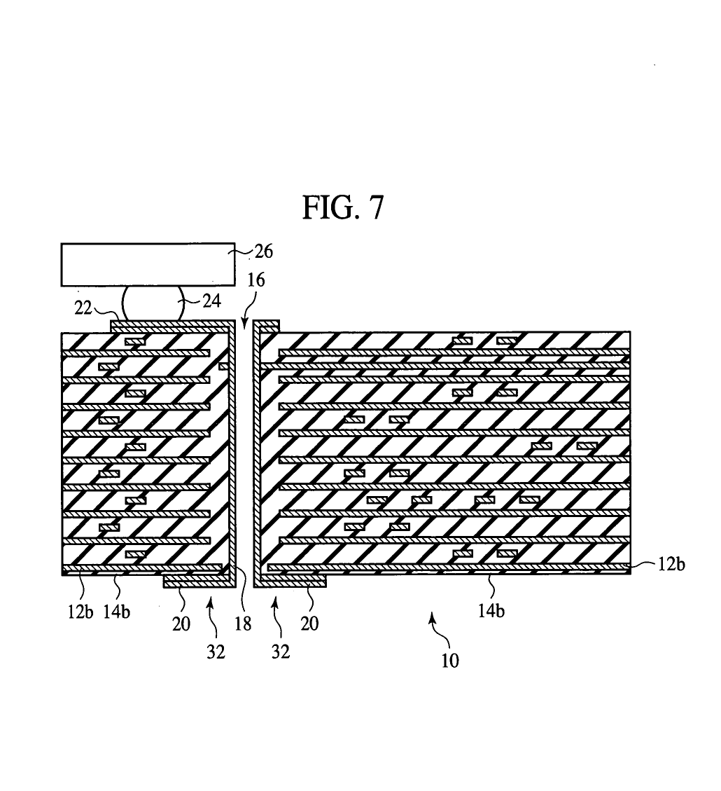

Otherwise, as exemplified in FIG. 7, an insulating layer 14b whose thickness is smaller than the other inter-layer insulating layers may be disposed between the interconnection layer 12b forming the ground layer and the via opening pad 20 to thereby increase the capacitance. In this case, the insulating layer 14b is formed of a very insulative material, such as polyimide film or others, whereby the capacitance can be easily increased while the sufficient insulation is ensured.

Next, the method for fabricating the circuit board according to the present embodiment will be explained with reference to FIGS. 8 to 10B.

First, a plurality of resin sheets 42a-42j having on both surfaces interconnection layers 12 each having a prescribed interconnection pattern, and a plurality of prepregs 44a-44i which are not thermally cured but semi-cured resin sheets are prepared.

Here, the interconnection layers 12a, 12b are formed respectively on the respective surfaces of the resin sheet 42a; the interconnection layers 12c, 12d are formed respectively on the respective surfaces of the resin sheet 42b; the interconnection layers 12e, 12f are formed respectively on the respective surfaces of the resin sheet 42c; the interconnection layers 12g, 12h are formed respectively on the respective surfaces of the resin sheet 42d; the interconnection layers 12i, 12j are formed respectively on the respective surfaces of the resin sheet 42e; the interconnection layers 12k, 12l are formed respectively on the respective surfaces of the resin sheet 42f; the interconnection layers 12m, 12n are formed respectively on the respective surfaces of the resin sheet 42g; the interconnection layers 12o, 12p are formed respectively on the respective surfaces of the resin sheet 42h; the interconnection layers 12q, 12r are formed respectively on the respective surfaces of the resin sheet 42i; and the interconnection layers 12s, 12t are formed respectively on the respective surfaces of the resin sheet 42j (see FIG. 8).

The interconnection layer 12q formed on the resin sheet 42i and the interconnection layer 12t formed on the resin sheet 42j are the interconnection layers to be connected to each other by the through-hole via 18, and the interconnection layer 12b formed on the resin sheet 42a is to be ground layer as the constant-voltage interconnection layer.

The clearance diameter (the diameter of the opening 30) in the region of the interconnection layer 12b, where the through-hole via is to be formed is, e.g., 800 μm.

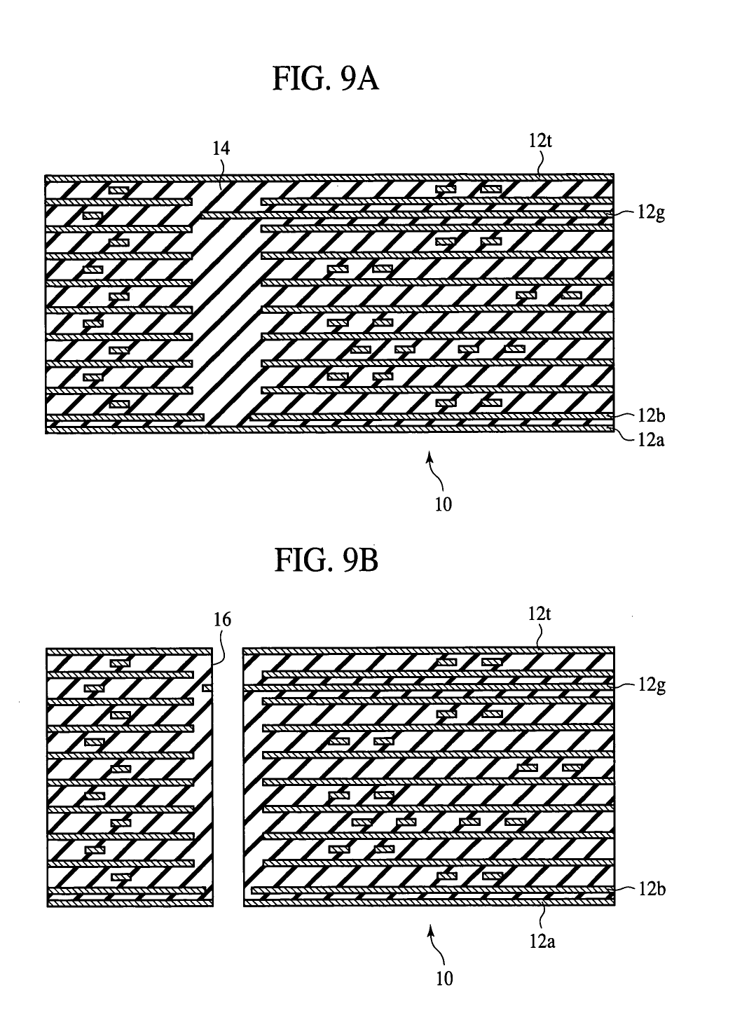

Then, the resin sheets 42a-42j with the interconnection layers 12a-12t formed on, and the prepregs 44a-44i are laid alternately one on another as shown in FIG. 8 while being aligned with each other and are subjected to vacuum heat press to be laminated at once. Thus, the prepregs 44a-44i are thermoset, and the substrate 10 comprising the interconnection layers 12a-12t laminated with the insulating layers 14 of a resin material disposed therebetween is prepared (FIG. 9A).

Then, the through-hole 16 is formed with a drill in the region of the substrate 10 where the through-hole via 18 is to be formed. At this time, the interconnection layer 12q, which is formed, extended over the region for the through-hole via 18 to be formed in as shown in FIG. 9A, has the side wall exposed in the through-hole 16 after the through-holes 16 has been formed (FIG. 9B).

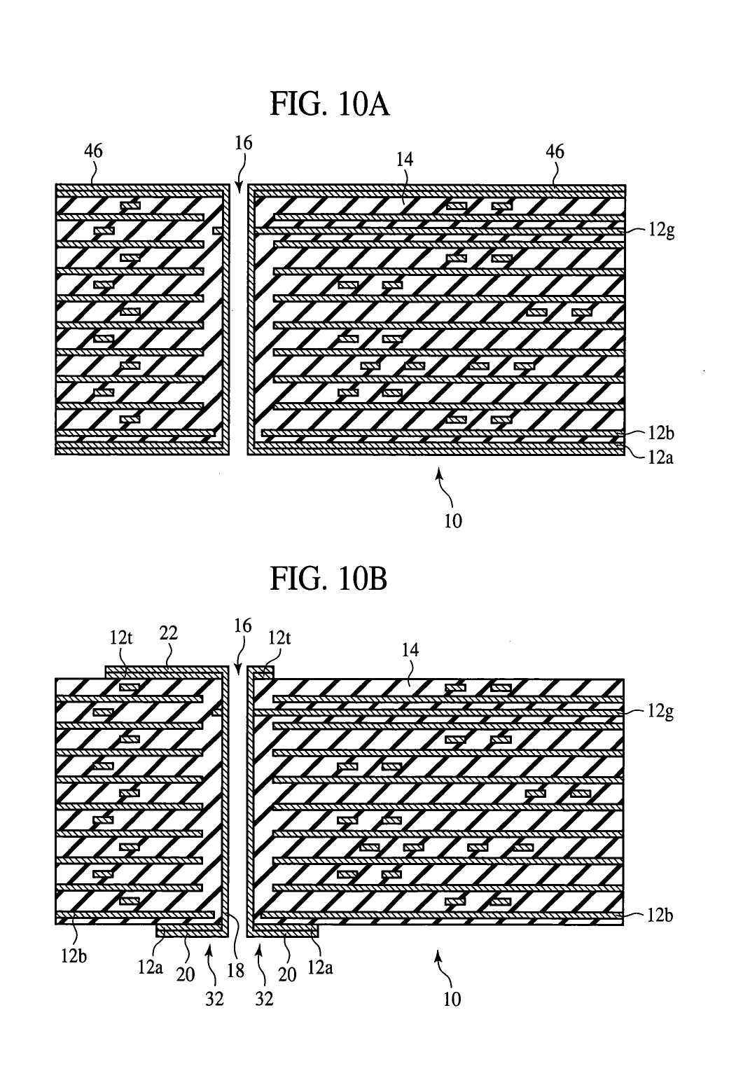

Then, a copper film 46 is formed by plating on the entire surface of the substrate 10 including the inside wall of the through-hole 16 (FIG. 10A). At this time, the formed copper film 46 is connected to the side wall of the interconnection layer 12q exposed in the through-hole 16.

Next, the copper film 46 and the interconnection layers 12a, 12t are patterned at once to form the through-hole via 18 including a via portion formed of the copper film 46 in the through-hole 16, the via opening pad 20 formed of the interconnection layer 12a and the copper film 46 in the region of the surface 10a of the substrate 10 surrounding the through-hole 16, and the electrode pad 22 formed of the interconnection layer 12t and the copper film 46 in the region of the surface 10b of the substrate 10 surrounding the through-hole 16 (FIG. 10B).

At this time, the outer diameter of the via opening pad 20 is, e.g., 1000 μm. Thus, an overlap is formed between the via opening pad and the interconnection layer 12b as the ground layer and the capacitor 32 having the insulating film 14 as the capacitor dielectric film is formed between the via opening pad 20 and the interconnection layer 12b.

Thus, the circuit board according to the present embodiment is fabricated.

In fabricating the circuit board shown in FIGS. 5 to 7, the resin sheet 42a may be formed of a ferroelectric material may be used (FIG. 5), the resin sheet 42a formed of a ferroelectric material selectively formed in the region where the via opening pad 20 is formed may be used (FIG. 6), or the resin sheet 42a may have a small thickness (FIG. 7).

As described above, according to the present embodiment, a capacitor including a pair of electrodes of the via opening pad and the ground layer is formed between the end of the surplus part of a through-hole via and the ground layer, whereby the resonance frequency of the open stub can be shifted. The capacitance of the capacitor can be controlled by an area of the overlap between the ground layer and the via opening pad, i.e., a clearance diameter of the ground layer and an outer diameter of the via opening pad, whereby a capacitor of an arbitrary capacitance can be realized only by changing patterns of the ground layer and/or the via opening pad by the conventional circuit board fabricating method. Thus, the reflection loss in an arbitrary frequency range can be decreased, and high-speed transmission circuit board having the transmission loss in the open stub decreased can be provided easily and at low costs.

### Modified Embodiments

The present invention is not limited to the above-described embodiments and can cover other various modifications.

For example, in the above-described embodiment, the capacitor 32 is provided at one end of the through-hole via 18. The capacitor 32 may be provided on each of the both ends of the through-hole via 18. Depending on the through-hole via 18, the open stubs might be formed on both surfaces of the substrate 10. In this case, it is preferable that the capacitor 32 is provided on each of both ends of the through-hole via 18.

In the above-described embodiments, the via opening pad 20 and the clearance of the ground layer are circular. However, the shape of the via opening pad 20 and the clearance of the ground layer are not essentially circular. It is a point of the present invention to form the capacitor by overlapping the via opening pad and the ground layer, and the present invention does not rely on patterns of the via opening pad and the ground layer.

In the above-described embodiment, 10 sheets of resin sheet with the interconnection layers formed on both surfaces are laminated to form the substrate 10. The number of the resin sheets is not limited to the number described above. It is not necessary to use a resin sheet with interconnection layers formed on both surfaces. A resin sheet with an interconnection layer formed on one surface, copper foil or others may be used to form the substrate.

What is claimed is:

1. A circuit board comprising:
a substrate formed of a plurality of interconnection layers and a plurality of insulating layers alternately laid one on another; and
a through-hole via including a via portion which is formed in a through-hole formed in the substrate and is electrically connected to a part of said plurality of interconnection layers, and a pad portion which is formed on a surface of the substrate in a region surrounding the through-hole and is connected to the via portion,
at least one of said plurality of interconnection layers being a constant-voltage interconnection layer fixed to a certain voltage, and an opening being formed for passing through the through-hole via out of connection with the constant-voltage interconnection layer in a region where the through-hole is formed,
the constant-voltage interconnection layer being the interconnection layer which is nearest the pad portion,
an outer diameter of the pad portion being larger than a diameter of the opening formed in the constant-voltage interconnection layer, and
the pad portion, the constant-voltage interconnection layer, and the insulating layer formed between the pad portion and the constant-voltage interconnection layer forming a capacitor.

2. A circuit board according to claim 1, wherein
the constant-voltage layer is a power supply layer or a ground layer.

3. A circuit board according to claim 1, wherein
the pad portion is provided at an end of the through-hole via, which does not contribute to the connection of the interconnection layers.

4. A circuit board according to claim 1, wherein
a thickness of the insulating layer between the pad portion and the constant-voltage interconnection layer is smaller than a thickness of the other insulating layers.

5. A circuit board according to claim 4, wherein
an insulating material forming the insulating layer between the pad portion and the constant-voltage interconnection layer is polyimide.

6. A circuit board according to claim 1, wherein
a dielectric constant of the insulating material forming the insulating layer between the pad portion and the constant-voltage interconnection layer is higher than a dielectric constant of an insulating material forming the other insulating layers.

7. A circuit board according to claim 6, wherein
a dielectric constant of the insulating material of the insulating layer formed between the pad portion and the constant-voltage interconnection layer in a region where the pad portion and the interconnection layer nearest to the pad portion are opposed to each other is higher than that in the rest region.

8. A circuit board according to claim 1, wherein
the insulating layer formed between the pad portion and the constant-voltage interconnection layer includes two or more layers of insulating materials of different dielectric constants.

9. A circuit board according to claim 1, wherein
a capacitance of the capacitor is so set that a reflection loss due to the through-hole via in an arbitrary frequency is decreased.

10. A circuit board according to claim 9, wherein
the capacitance is five or more times a capacitance with the outer diameter of the pad portion being smaller than the diameter of the opening formed in the constant-voltage interconnection layer.

11. A circuit board according to claim 9, wherein
the capacitance is fifty or more times a capacitance with the outer diameter of the pad portion being smaller than the diameter of the opening formed in the constant-voltage interconnection layer.

12. A circuit board according to claim 9, wherein
the capacitance is so set that when a center frequency of a band of the arbitrary frequency is 100%, a frequency at the resonance point of the through-hole via is not more than 70% or not less than 130%.
